(19) United States
(12) Patent Application Publication
(10) Pub. No.: US 2021/0335774 A1
(43) Pub. Date: Oct. 28, 2021

(54) SEMICONDUCTOR INTEGRATED CIRCUIT DEVICE

(71) Applicant: SOCiONEXT INC., Kanagawa (JP)

(72) Inventor: Hironobu OCHIAI, Yokohama-shi (JP)

(21) Appl. No.: 17/370,912

(22) Filed: Jul. 8, 2021

Related U.S. Application Data
(63) Continuation of application No. PCT/JP2019/000367, filed on Jan. 9, 2019.

(51) Int. Cl. H01L 27/02; H01L 23/528; H01L 23/522

(52) U.S. Cl. CPC H01L 27/0207; H01L 23/5223; H01L 23/5286

(57) ABSTRACT

Between strap power supply lines that supply a power supply potential VDD, standard cell columns and standard cell columns are arranged alternately in a Y-direction. Out of capacitor cells and correction cells, only the capacitor cells are arranged in the standard cell columns, and only the correction cells are arranged in the standard cell columns.

### CROSS-REFERENCE TO RELATED APPLICATIONS

This is a continuation of International Application No. PCT/JP2019/000367 filed on Jan. 9, 2019. The entire disclosure of this application is incorporated by reference herein.

### TECHNICAL FIELD

The present disclosure relates to a semiconductor integrated circuit device including standard cells, and more particularly to a semiconductor integrated circuit device including decoupling capacitor cells and correction cells as standard cells.

### BACKGROUND ART

Standard cell methodology is known as a method of forming a semiconductor integrated circuit on a semiconductor substrate. The standard cell methodology is a method of designing an LSI chip by preparing in advance, as standard cells, basic units (e.g., an inverter, a latch, a flip-flop, or a full adder) with specific logic functions, arranging the standard cells on a semiconductor substrate, and connecting the standard cells by interconnects.

In recent years, with an increase in the scales, an increase in the speeds, and a decrease in the voltages of the LSI circuits, the influence of power supply voltage drop and power supply noise increases. As standard cells for reducing the influence, decoupling capacitor cells are arranged in a semiconductor integrated circuit device.

On the other hand, correction cells are arranged as standard cells in a semiconductor integrated circuit device to address operation defects or addition of functions after designing the semiconductor integrated circuit device, with less mask correction (e.g., correction of the masks of some of metal interconnect layers).

Patent Document 1 discloses a semiconductor integrated circuit device and a method of designing the device. The device includes a plurality of standard cell columns in which decoupling capacitor cells (hereinafter also referred to simply as “capacitor cells” as appropriate) and correction cells are arranged.

### CITATION LIST

### Patent Document

PATENT DOCUMENT 1: Japanese Unexamined Patent Publication No. 2007-234857

### SUMMARY OF THE INVENTION

### Technical Problem

Patent Document 1 discloses the arrangement order of the decoupling capacitor cells and the correction cells, but fails to disclose the arrangement pattern of the decoupling capacitor cells and the correction cells.

A semiconductor integrated circuit device including standard cells, each power supply line in a standard cell column includes a decoupling capacitor cell in one preferred embodiment to reduce power supply voltage drop and power supply noise generated in the power supply line. In order to reduce the interconnection delay of an interconnect for each correction cell, a correction cell is located near the position of an operation defect or a position to which a function is to be added in one preferred embodiment. However, in order to meet these requirements, a semiconductor integrated circuit device requires a large number of decoupling capacitor cells and correction cells, which increases the area of the semiconductor integrated circuit device.

To address the problem, the present disclosure provides a semiconductor integrated circuit device using correction cells and decoupling capacitor cells.

### Solution to the Problem

According to the present disclosure, a semiconductor integrated circuit device includes: a plurality of power supply lines that extend in a first direction; a plurality of cell columns each including a plurality of standard cells aligned in the first direction, and are interposed between a pair of the power supply lines; and a first strap power supply line and a second strap power supply line that extend above the plurality of cell columns in a second direction perpendicular to the first direction, are adjacent to each other at a distance in the first direction, and are configured to supply a same power supply voltage. The plurality of power supply lines include first power supply lines and second power supply lines alternately in the second direction. The first power supply lines are configured to supply a first power supply voltage. The second power supply lines are configured to supply a second power supply voltage different from the first power supply voltage. The plurality of cell columns include, in a first region between the first and second strap power supply lines, first cell columns and second cell columns alternately in the second direction. Out of capacitor cells and correction cells, only the capacitor cells are arranged in the first cell columns, and only the correction cells are arranged in the second cell columns.

According to this aspect, the plurality of cell columns include, in the first region between the first and second strap power supply lines, the first cell columns and the second cell columns. Out of the capacitor cells and the correction cells, only the capacitor cells are arranged in the first cell columns, and only the correction cells are arranged in the second cell columns. The first and second cell columns are arranged alternately in the second direction. That is, the capacitor cells and the correction cells are arranged alternately in the cell columns aligned in the second direction. Accordingly, a smaller number of the capacitor cells and the correction cells can thus be reliably arranged in the semiconductor integrated circuit device.

The first cell columns including the capacitor cells are arranged in every two columns in the second direction. Accordingly, each of the power supply lines is connected to associated ones of the capacitor cells, which reduces local power supply voltage drop and power supply noise inside an associated circuit block.

The second cell columns including the correction cells are arranged in every two columns in the second direction. Accordingly, the correction cells are highly likely to be arranged near the positions of operation defects or the positions to which functions are to be added, which reduces interconnection delays for the correction cells.

### Advantages of the Invention

The present disclosure provides a semiconductor integrated circuit device with a smaller area, reduced power supply effects or power supply noise in power supply lines, and reduced interconnection delays for correction cells.

### BRIEF DESCRIPTION OF THE DRAWINGS

FIG. 1 is a circuit diagram showing an example of a decoupling capacitor cell.

FIG. 2 includes illustrations (a) and (b) that are circuit diagrams each showing an example of a correction cell.

FIG. 3 is a top view showing a layout configuration of a semiconductor integrated circuit device according to a first embodiment.

FIG. 4 is a flowchart showing a procedure of designing the semiconductor integrated circuit device.

FIG. 5 is a top view showing a layout configuration of the semiconductor integrated circuit device according to the first embodiment after executing step S2.

FIG. 6 is a top view showing a layout configuration of the semiconductor integrated circuit device according to the first embodiment after executing step S3.

FIG. 7 is a top view showing a layout configuration of the semiconductor integrated circuit device according to the first embodiment after executing step S5.

FIG. 8 is a top view showing a layout configuration of a semiconductor integrated circuit device according to a second embodiment.

FIG. 9 is a top view showing a layout configuration of the semiconductor integrated circuit device according to the second embodiment after executing step S5.

### DESCRIPTION OF EMBODIMENTS

Embodiments will be described with reference to the drawings. In the following embodiments, a semiconductor integrated circuit device includes a plurality of standard cells (hereinafter also simply referred to as “cells” as appropriate).

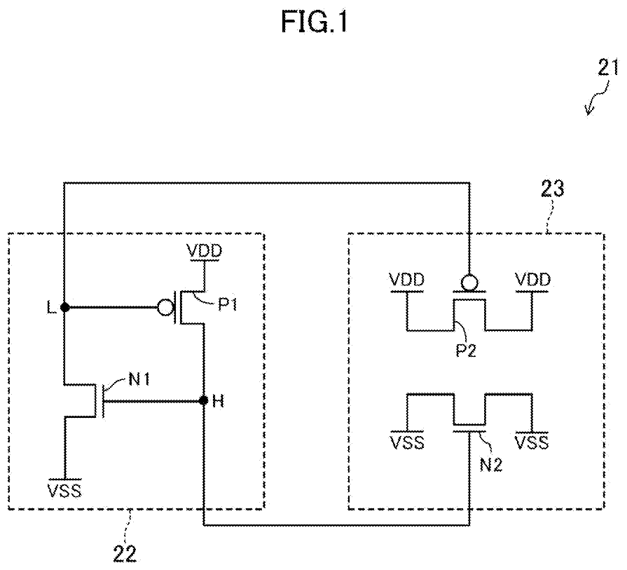

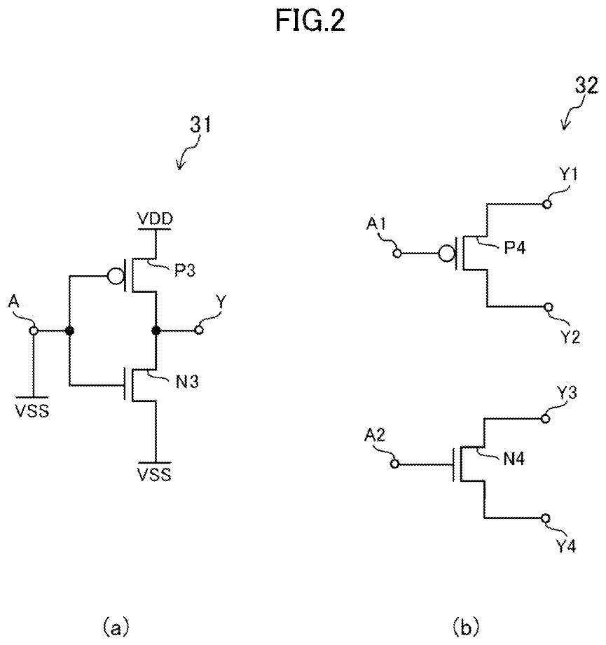

First, decoupling capacitor cells (hereinafter also simply referred to as “capacitor cells” as appropriate) and correction cells will be described. FIG. 1 is a circuit diagram showing a configuration example of a decoupling capacitor cell. In FIG. 2, illustrations (a) and (b) are circuit diagrams each showing a configuration example of a correction cell. In FIGS. 1 and 2, the configuration is shown using circuit diagram symbols, but in practice, a layout is formed including diffusion regions, gate lines, metal lines, and other elements.

The “decoupling capacitor cell” is a standard cell provided to reduce power supply voltage drop and power supply noise in a semiconductor integrated circuit device. The decoupling capacitor cell is formed using a P-type metal-oxide-semiconductor (MOS) (PMOS) transistor and an N-type MOS (NMOS) transistor. Each of the P- and N-type MOS transistors (hereinafter simply referred to as “P- and N-type transistors”) includes a drain and a source each connected to one of power supplies VDD and VSS, and a gate applied with power with one of opposite polarities. In this specification, VDD and VSS represent the power supplies and the voltages supplied from the power supplies.

As shown in FIG. 1, the decoupling capacitor cell is configured as a decoupling capacitor cell circuit 21. The decoupling capacitor cell circuit 21 includes a fixed value output unit 22 and a decoupling capacitor unit 23.

The fixed value output unit 22 includes a P-type transistor P1 and an N-type transistor N1. The decoupling capacitor unit 23 includes a P-type transistor P2 and an N-type transistor N2. The P-type transistor P1 has a source connected to a power supply VDD, a gate connected to the gate of the P-type transistor P2 and the drain of the N-type transistor N1, and a drain connected to the gate of the N-type transistor N1 and the gate of the N-type transistor N2. The N-type transistor N1 has a source connected to a power supply VSS. The P-type transistor P2 has a source and a drain each connected to a power supply VDD. The N-type transistor N2 has a drain and a source each connected to a power supply VSS. The fixed value output unit 22 always applies voltages VSS and VDD to the gates of the P- and N-type transistors P2 and N2, respectively. Accordingly, the P- and N-type transistors P2 and N2 are always turned on, and the gate oxide films of the P- and N-type transistors P2 and N2 function as capacitors.

The decoupling capacitor cell circuit 21 may not include the fixed value output unit 22. In this case, the gate of the P-type transistor P2 and the gate of the N-type transistor N2 are directly connected to the power supplies VSS and VDD, respectively. In addition, the decoupling capacitor cell may have a configuration using no transistor but an inter-line capacitor.

The “correction cell” is a standard cell used at an occurrence of an operation failure or addition of a function after the arrangement and interconnection of the cells in logic blocks.

As shown in the illustration (a) of FIG. 2, the correction cell is configured as a correction cell circuit 31. The correction cell circuit 31 includes a P-type transistor P3 and an N-type transistor N3.

The P-type transistor P3 has a source connected to a power supply VDD, a gate connected to an input terminal A and the gate of the N-type transistor N3, and a drain connected to an output terminal Y and the drain of the N-type transistor N3. The N-type transistor N3 has a source connected to a power supply VSS. That is, the correction cell circuit 31 is an inverter circuit that inverts signals input through the input terminal A and outputs the inverted signals through the output terminal Y.

As shown in the illustration (a) of FIG. 2, in the correction cell circuit 31, one of the power supplies VSS is connected to the input terminal A in advance, but the output terminal Y is unconnected. When an inverter circuit needs to be added in correcting the semiconductor integrated circuit device, the power supply VSS is disconnected from the input terminal A, and the input terminal A and the output terminal Y are connected to other circuits. Accordingly, the semiconductor integrated circuit device can be corrected into a desired circuit.

The logic circuit configured as the correction cell may be a logic circuit, other than the correction cell circuit 31 functioning as an inverter circuit, or may not be a logic circuit with a specific function. For example, as shown in the illustration (b) of FIG. 2, the correction cell may be configured as a correction cell circuit 32 including a P-type transistor P4 and an N-type transistor N4. The P-type transistor P4 has a gate connected to a terminal A1, a source connected to a terminal Y1, and a drain connected to a terminal Y2. The N-type transistor N4 has a gate connected to a terminal A2, a source connected to a terminal Y3, and a drain connected to a terminal Y4. In the correction cell circuit 32, the terminals A1, A2, and Y1 to Y4 are unconnected in advance. In correcting a semiconductor integrated circuit device, the terminals A1, A2, and Y1 to Y4 are connected to configure a desired circuit, thereby achieving the correction.

### First Embodiment

Next, a structure of a semiconductor integrated circuit device according to a first embodiment will be described.

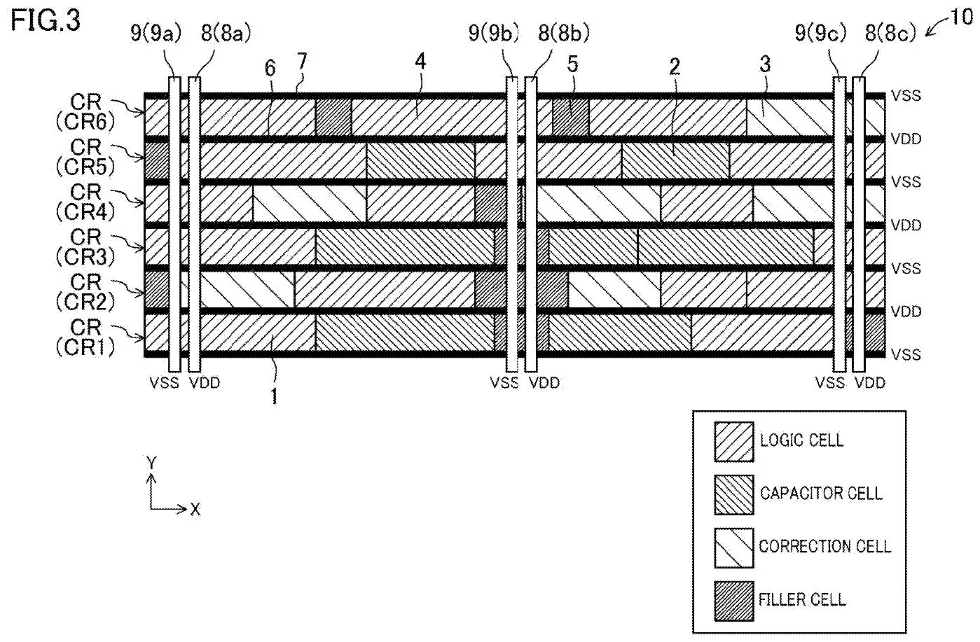

FIG. 3 is a top view illustrating a configuration of the semiconductor integrated circuit device according to the first embodiment. FIG. 3 shows a simplified layout pattern of circuit blocks including capacitor cells and correction cells (the same applies to the subsequent top views). A semiconductor integrated circuit device 10 shown in FIG. 3 includes, on its substrate, a plurality of standard cells 1. A plurality of (six in FIG. 3) standard cell columns CR, each of which includes a plurality of standard cells 1 aligned in the X-direction (i.e., in the horizontal direction of the drawing or a first direction), are arranged in the Y-direction (i.e., in the vertical direction of the figure, or a second direction perpendicular to the first direction). Each standard cell 1 is a basic circuit element functioning as an inverter or a logic circuit, for example. By the arrangement and interconnection of the standard cells in combination, a semiconductor integrated circuit device can be designed and manufactured which fulfils predetermined functions.

The standard cell columns CR are arranged in the order of CR1 to CR6 from blow to above in the figure. In FIG. 3 or other figures, the odd-numbered standard cell columns CR (i.e., CR1, CR3, and CR5) from the bottom of the figure are referred to as “odd-numbered standard cell columns CR”, whereas the even-numbered standard cell columns CR (i.e., CR2, CR4, and CR6) from the bottom of the figure are referred to as “even-numbered standard cell columns CR”.

Between the standard cell columns CR, power supply lines 6 (marked with “VDD” on the right) that supply the power supply potential VDD to the standard cells 1, and power supply lines 7 (marked with “VSS” on the right) that supply the power supply potential VSS to the standard cells 1 are arranged alternately. The power supply lines 6 and 7 are both arranged to extend in the X-direction. Each power supply line 6 supplies the power supply potential VDD to the standard cell columns CR on its both sides in the Y-direction. Each power supply line 7 supplies the power supply potential VSS to the standard cell columns CR on its both sides in the Y-direction.

The semiconductor integrated circuit device 10 includes strap power supply lines 8 and 9 above the power supply lines 6 and 7 so as to extend in the Y-direction. The strap power supply lines 8 are connected to the power supply lines 6 via contacts, and supplies the power supply potential VDD to the standard cells 1 below the strap power supply lines 8. The strap power supply lines 9 are connected to the power supply lines 7 via contacts, and supplies the power supply potential VSS to the standard cells 1 below the strap power supply lines 9. In FIG. 3, the contacts between the power supply lines 6 and the strap power supply lines 8 and the contacts between the power supply lines 7 and the strap power supply lines 9 are not shown.

As shown in FIG. 3, the strap power supply lines 8 and 9 are arranged alternately in the X-direction. For example, the strap power supply lines 8 (namely 8a, 8b, and 8c) are arranged at regular intervals, and the strap power supply lines 9 (namely 9a, 9b, and 9c) are arranged at regular intervals.

In FIG. 3, the strap power supply lines 8a and 9a, the strap power supply lines 8b and 9b, and the strap power supply lines 8c and 9c are adjacent to each other. Note that the strap power supply lines that supply the power supply potential VDD and the strap power supply lines that supply the power supply potential VSS are not necessarily adjacent to each other.

The standard cells 1 in the standard cell columns CR include capacitor cells 2, correction cells 3, logic cells 4, and filler cells 5.

As described above, the capacitor cells 2 are standard cells provided to reduce power supply voltage drop and power supply noise inside the semiconductor integrated circuit device 10. As shown in FIG. 3, the capacitor cells 2 include a plurality of types of capacitor cells in different sizes in the X-direction.

As described above, the correction cells 3 are standard cells used at an occurrence of operation failures or addition of functions after the arrangement and interconnection of the cells in the logic blocks. As shown in FIG. 3, the correction cells 3 include a plurality of types of correction cells in different sizes in the X-direction. The correction cells 3 have different sizes in the X-direction depending on the logic circuits included therein.

The logic cells 4 are standard cells arranged on the substrate to achieve desired circuits. Each logic cells 4 includes, for example, a P-type transistor, an N-type transistor, and other elements, each having a predetermined logic function.

The filler cells 5 are standard cells which have no logic functions, do not contribute to the logic functions of the circuit blocks, and are arranged to fill the gaps between the logic cells, the capacitor cells, and the correction cells. Each filler cell 5 may include a transistor (or a dummy transistor) with no logic function.

Next, a method of designing the semiconductor integrated circuit device according to the first embodiment will be described with reference to FIGS. 3 to 7.

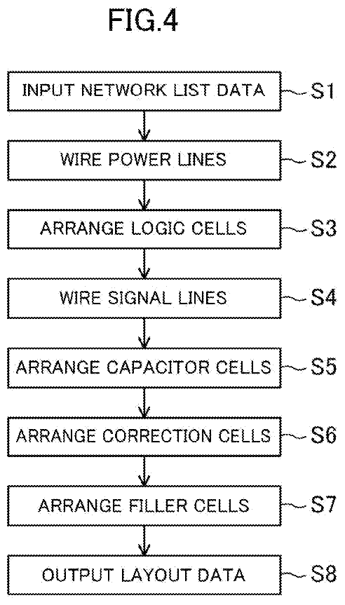

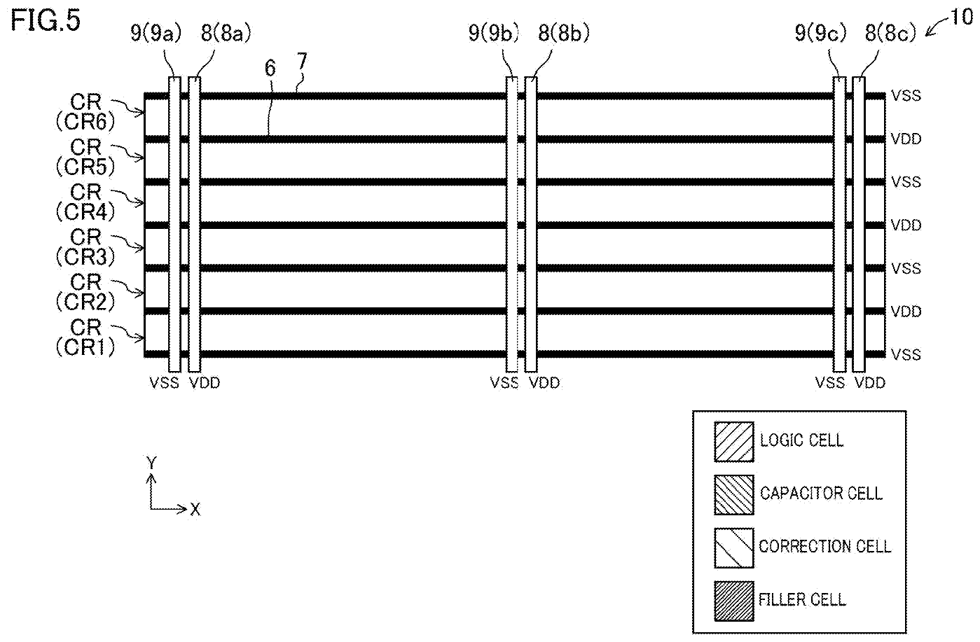

FIG. 4 is a flowchart showing the method of designing the semiconductor integrated circuit device. FIGS. 5 to 7 are top views showing the layout configuration of the semiconductor integrated circuit device after executing steps S2, S3, and S5, respectively, in the flow of FIG. 4.

Used in designing the semiconductor integrated circuit device is a device for outputting layout data on the semiconductor integrated circuit device for achieving a desired circuit based on input network list data, for example, a computer for designing the semiconductor integrated circuit device.

Specifically, in step S1, a network list data indicating the logic cells 4 constituting the desired circuits and connections between the logic cells 4 is input to the design computer.

In step S2, the power supply lines 6 and 7 are arranged on the substrate for the layout data. As shown in FIG. 5, the power supply lines 6 and 7 extending in the X-direction are arranged alternately in the Y-direction. The power supply lines 6 and 7 are arranged at intervals so that each standard cell column CR is interposed between a pair of the power supply lines 6 and 7 adjacent in the Y-direction.

Above the power supply lines 6 and 7, the strap power supply lines 8 and 9 extending in the Y-direction are arranged alternately in the X-direction. As shown in FIG. 5, the strap power supply lines 8a and 9a, the strap power supply lines 8b and 9b, and the strap power supply lines 8c and 9c are arranged on the left, at the center, and on the right of the figure, respectively. Although not shown, the strap power supply lines 8a to 8c are connected to the power supply lines 6 via the contacts, whereas the strap power supply lines 9a to 9c are connected to the power supply lines 7 via the contacts.

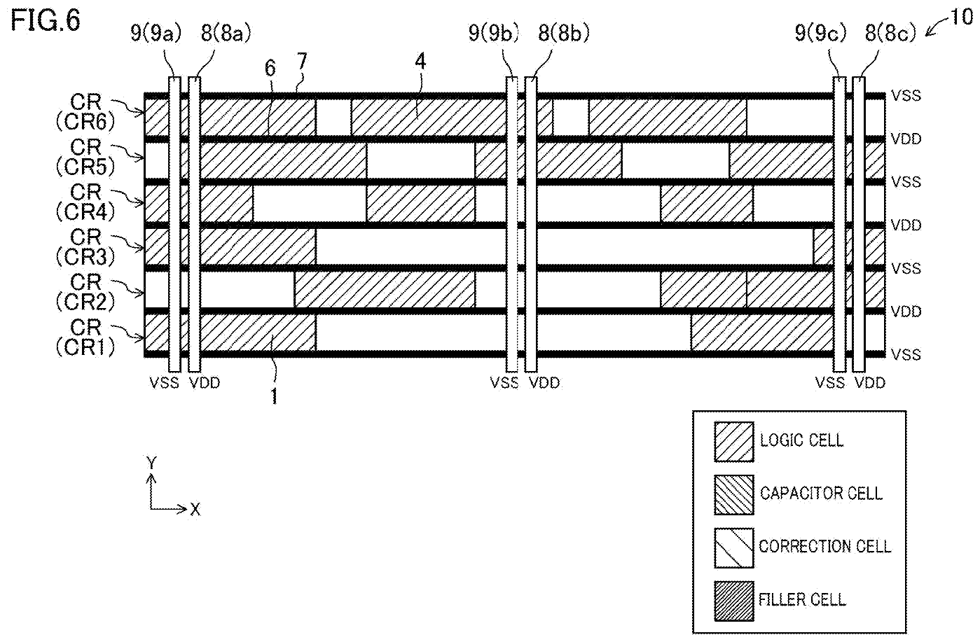

In step S3, the logic cells 4 are arranged on the substrate based on the network list data. As shown in FIG. 6, the logic cells 4 are arranged in the standard cell columns CR1 to CR6 so as to achieve desired circuit configurations included in the network list data.

In step S4, signal lines are connected based on the network list data. Although not shown, the signal lines are connected between the logic cells 4 arranged on the substrate based on the network list data.

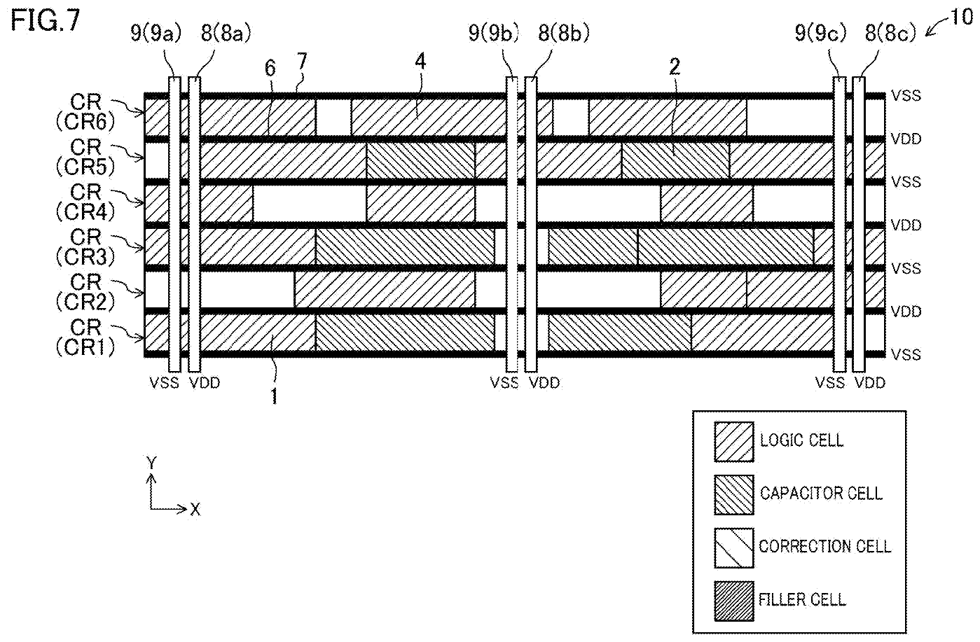

In step S5, the capacitor cells 2 are arranged. As shown in FIG. 6, in the standard cell columns CR, there are empty regions (i.e., white regions in the standard cell columns CR1 to CR6) with no logic cells 4. In these empty regions, the capacitor cells 2 are arranged. As shown in FIG. 7, the capacitor cells 2 are arranged only in the empty regions of the standard cell columns CR1, CR3, and CR5 which are the odd-numbered standard cell columns CR. That is, the capacitor cells 2 are arranged in every two standard cell columns CR aligned in the Y-direction. Note that the capacitor cells 2 are arranged as much as possible in the empty regions of the odd-numbered standard cell columns CR.

In step S6, the correction cells 3 are arranged. As shown in FIG. 7, in the standard cell columns CR, there are empty regions (i.e., white regions in the standard cell columns CR1 to CR6) with neither capacitor cells 2 nor logic cells 4. In these empty regions, the correction cells 3 are arranged. Specifically, the correction cells 3 are arranged in the empty regions with no logic cells 4 in the standard cell columns CR2, CR4, and CR6 which are the even-numbered standard cell columns CR. That is, the correction cells 3 are arranged only in the even-numbered standard cell columns CR2, CR4, and CR6 with no capacitor cells 2. Accordingly, the correction cells 3 are arranged in every two standard cell columns CR aligned in the Y-direction. No that the correction cells 3 are arranged as much as possible in the empty regions of the even-numbered standard cell columns CR.

In the step S7, the filler cells 5 are arranged. With the capacitor cells 2, the correction cells 3, the logic cells 4, and the filler cells 5 arranged on the substrate, the layout configuration as shown in FIG. 3 is obtained. The filler cells 5 are arranged in empty regions of the standard cell columns CR with none of the capacitor cells 2, the correction cells 3, or the logic cells 4. The filler cells 5 are arranged in extremely small empty regions of the standard cell columns CR where none of the capacitor cells 2, the correction cells 3, or the logic cells 4 can be arranged.

In step S8, the design computer outputs the layout data on the semiconductor integrated circuit device 10 including the capacitor cells 2, the correction cells 3, the logic cells 4, and the filler cells 5.

With the configuration described above, between the pairs of strap power supply lines 8a and 9a and 8b and 9b, and between the pairs of strap power supply lines 8b and 9b and 8c and 9c, which are adjacent to each other in the X-direction, the capacitor cells 2 are arranged in the odd-numbered standard cell columns CR (i.e., CR1, CR3, and CR5), whereas the correction cells 3 are arranged in the even-numbered standard cell columns CR (i.e., CR2, CR4, and CR6). That is, the standard cell columns CR (i.e., CR1, CR3, and CR5) and the standard cell columns CR (i.e., CR2, CR4, and CR6) are arranged alternately in the Y-direction. Out of the capacitor cells 2 and the correction cells 3, only the capacitor cells 2 are arranged in the standard cell columns CR (i.e., CR1, CR3, and CR5), and only the correction cells 3 are arranged in the standard cell columns CR (i.e., CR2, CR4, and CR6). Accordingly, the capacitor cells 2 and the correction cells 3 are alternately arranged in the standard cell columns CR aligned in the Y-direction. A smaller number of the capacitor cells 2 and the correction cells 3 can thus be reliably arranged in the semiconductor integrated circuit device 10.

The capacitor cells 2 are interposed between adjacent pairs of the power supply lines 6 and 7 and connected to these power supply lines 6 and 7. The capacitor cells 2 are arranged in every two standard cell columns CR aligned in the Y-direction. That is, each of the power supply lines 6 and 7 is connected to associated ones of the capacitor cells 2. This configuration reduces local power supply voltage drop and power supply noise in the circuit blocks.

The correction cells 3 are arranged in every two standard cell columns CR aligned in the Y-direction. Accordingly, the correction cells are highly likely to be arranged near the positions of operation defects or the positions to which functions are to be added, which reduces interconnection delays for the correction cells.

While the capacitor cells 2 are arranged in the odd-numbered standard cell columns CR and the correction cells 3 are arranged in the even-numbered standard cell columns CR, the arrangement is not limited thereto. The capacitor cells 2 may be arranged in the even-numbered standard cell columns CR, and the correction cells 3 may be arranged in the odd-numbered standard cell columns CR.

### Second Embodiment

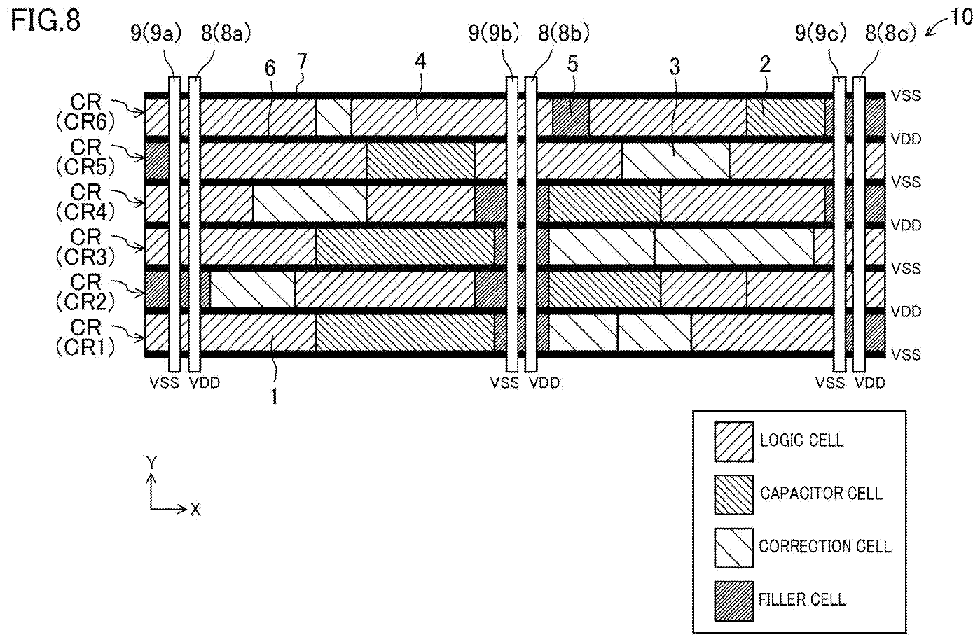

FIG. 8 is a top view showing a configuration of a semiconductor integrated circuit device according to a second embodiment. The arrangement of the standard cell columns CR1 to CR6, the power supply lines 6 and 7, the strap power supply lines 8 and 9, and the logic cells 4 are the same as those in FIG. 3. The description thereof will thus be omitted.

In FIG. 3, between the pairs of strap power supply lines 8a and 9a and 8b and 9b and between the pairs of strap power supply lines 8b and 9b and 8c and 9c, the capacitor cells 2 are arranged in the odd-numbered standard cell columns CR, and the correction cells 3 are arranged in the even-numbered standard cell columns CR. That is, the capacitor cells 2 and the correction cells 3 are arranged in the same manner between the pairs of strap power supply lines 8a and 9a and 8b and 9b, and between the pairs of strap power supply lines 8b and 9b and 8c and 9c.

On the other hand, in FIG. 8, the capacitor cells 2 and the correction cells 3 are arranged between the pairs of strap power supply lines 8a and 9a and 8b and 9b differently from those between the pairs of strap power supply lines 8b and 9b and 8c and 9c.

Specifically, the capacitor cells 2 are arranged in the odd-numbered standard cell columns CR (i.e., CR1, CR3, and CR5) between the pairs of strap power supply lines 8a and 9a and 8b and 9b, and in the even-numbered standard cell columns CR (i.e., CR2, CR4, and CR6) between the pairs of strap power supply lines 8b and 9b and 8c and 9c.

The correction cells 3 are arranged in the even-numbered standard cell columns CR (i.e., CR2, CR4, and CR6) between the pairs of strap power supply lines 8a and 9a and 8b and 9b, and the odd-numbered standard cell columns CR between the pairs of strap power supply lines 8b and 9b and 8c and 9c.

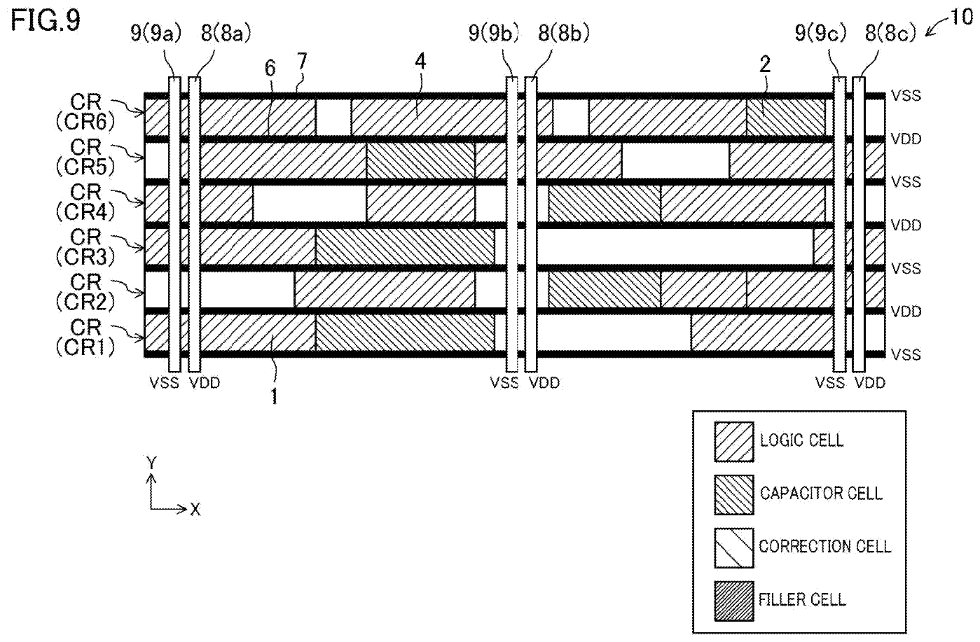

Next, a method of designing the semiconductor integrated circuit device according to the second embodiment will be described with reference to FIGS. 4, 6, 8, and 9. FIG. 9 shows a layout configuration of the semiconductor integrated circuit device after executing step S5.

In FIG. 4, steps S1 to S4, S7, and S8 are the same as those in the first embodiment. The description thereof will thus be omitted.

In step S5, the capacitor cells 2 are arranged. As shown in FIGS. 6 and 9, the capacitor cells 2 are arranged in the empty regions of the odd-numbered standard cell columns CR (i.e., CR1, CR3, and CR5) between the pairs of strap power supply lines 8a and 9a and 8b and 9b, and in the empty regions of the even-numbered standard cell columns CR (i.e., CR2, CR4, and CR6) between the pairs of strap power supply lines 8b and 9b and 8c and 9c. That is, the capacitor cells 2 are arranged on both sides of the power supply lines 6 and 7 between the pairs of strap power supply lines 8a and 9a and 8c and 9c.

In step S6, the correction cells 3 are arranged. As shown in FIGS. 8 and 9, the correction cells 3 are arranged in the empty regions of the even-numbered standard cell columns CR (i.e., CR2, CR4, and CR6) between the pairs of strap power supply lines 8a and 9a and 8b and 9b, and in the empty regions of the odd-numbered standard cell columns CR (i.e., CR1, CR3, and CR5) between the pairs of strap power supply lines 8b and 9b and 8c and 9c.

The configuration in FIG. 9 provides the same advantages as in FIG. 3.

For example, assume that power supply noise occurs in the power supply line 6 between the standard cell columns CR3 and CR4. In this case, the power supply noise propagates through the capacitor cells 2 connected to this power supply line 6 to the power supply lines 7 on both sides of the power supply line 6 (i.e., the power supply line 7 between the standard cell columns CR2 and CR3 and the power supply line 7 between the standard cell columns CR4 and CR5). That is, at an occurrence of power supply noise in any one of the power supply lines 6 and 7, the power supply noise propagates through the associated capacitor cells 2 to the power supply lines 6 or 7 on both sides. Accordingly, the power supply noise occurring in the power supply lines 6 or 7 is dispersed, which reduces the influence of the power supply noise.

Note that the positions of the capacitor cells 2 and the correction cells 3 are interchangeable. In this case, the capacitor cells 2 are arranged in the odd-numbered standard cell columns CR between the pairs of strap power supply lines 8a and 9a and 8b and 9b, and in the even-numbered standard cell columns CR between the pairs of strap power supply lines 8b and 9b and 8c and 9c. The correction cells 3 are arranged in the even-numbered standard cell columns CR between the pairs of strap power supply lines 8a and 9a and 8b and 9b, and the odd-numbered standard cell columns CR between the pairs of strap power supply lines 8b and 9b and 8c and 9c.

In the embodiments described above, the correction cells 3 are arranged after the capacitor cells 2. The order is however not limited thereto. The capacitor cells 2 may be arranged after the correction cells 3.

In the embodiments described above, the six standard cell columns are aligned in the Y-direction. The number is however not limited thereto. Two or more standard cell columns suffice.

### INDUSTRIAL APPLICABILITY

According to the present disclosure, a semiconductor integrated circuit device including standard cells allows, with a smaller area, arrangement of decoupling capacitor cells and correction cells.

### DESCRIPTION OF REFERENCE CHARACTERS

1 Standard Cell
2 Decoupling Capacitor Cell
3 Correction Cell
6, 7 Power Supply Line
8, 9 (8a to 8c, 9a to 9c) Strap Power Supply Line
CR (CR1 to CR6) Standard Cell Column

1. A semiconductor integrated circuit device, comprising:
a plurality of power supply lines extending in a first direction;
a plurality of cell columns that each include a plurality of standard cells aligned in the first direction, and are interposed between a pair of the power supply lines;
a first strap power supply line and a second strap power supply line that extend above the plurality of cell columns in a second direction perpendicular to the first direction, are adjacent to each other at a distance in the first direction, and are configured to supply a same power supply voltage;
the plurality of power supply lines including first power supply lines and second power supply lines alternately in the second direction, the first power supply lines being configured to supply a first power supply voltage, the second power supply lines being configured to supply a second power supply voltage different from the first power supply voltage; and
the plurality of cell columns including, in a first region between the first and second strap power supply lines, first cell columns and second cell columns alternately in the second direction, out of capacitor cells and correction cells, only the capacitor cells being arranged in the first cell columns, and only the correction cells being arranged in the second cell columns.

2. The device of claim 1, further comprising:
a third strap power supply line that extends above the plurality of cell columns in the second direction, is adjacent to the second strap power supply line at a distance in a position opposite to the first strap power supply line in the first direction, and is configured to supply the same power supply voltage as the first and second strap power supply lines, wherein
in a region between the second and third strap power supply lines, out of the capacitor cells and the correction cells, only the capacitor cells are arranged in the first cell columns, and only the correction cells are arranged in the second cell columns.

3. The device of claim 1, further comprising:
a third strap power supply line that extends above the plurality of cell columns in the second direction, is adjacent to the second strap power supply line at a distance in a position opposite to the first strap power supply line in the first direction, and is configured to supply the same power supply voltage as the first and second strap power supply lines, wherein
in a region between the second and third strap power supply lines, out of the capacitor cells and the correction cells, only the correction cells are arranged in the first cell columns, and only the capacitor cells are arranged in the second cell columns.
